(19) United States
(12) Patent Application Publication
(10) Pub. No.: US 2008/0023824 A1
(43) Pub. Date: Jan. 31, 2008

(54) Double-sided die

(75) Inventor: James Fred Salzman, Anna, TX (US)

Correspondence Address: TEXAS INSTRUMENTS INCORPORATED, P O BOX 655474, M/S 3999, DALLAS, TX, 75265, US

(73) Assignee: Texas Instruments

(21) Appl. No.: 11/495,505

(22) Filed: Jul. 28, 2006

(51) Int. Cl. H01L 23/34

(52) U.S. Cl. 257/724

(57) ABSTRACT

In a described implementation for double-sided die utilization, a die includes at least one die feature on a first side and at least one die feature on a second side. The die features on the first and second sides are electrically interconnected by way of through vias.

### BACKGROUND

Computers, mobile phones, personal digital assistants (PDAs), and consumer electronics are all examples of electronic devices. Electronic devices operate using integrated circuits (ICs). ICs are semiconductors on which circuits are fabricated. The ICs enable complicated electronic circuits involving many different functions to be realized in a relatively small physical space. Consequently, IC technology enables the capabilities of electronic devices to far exceed those that would be possible without it, and IC technology also enables those capabilities to continually increase.

### SUMMARY

In a described implementation for double-sided die utilization, a die includes at least one die feature on a first side and at least one die feature on a second side. The die features on the first and second sides are electrically interconnected by way of through vias. The double-sided die can be attached to a printed circuit board (PCB) for an electronic device. In another described implementation, a die may be singulated from a wafer that has been thinned so that through vias can be established to extend from one side of the die to the other. Other method, system, apparatus, device, scheme, processing, arrangement, etc. implementations are described herein.

### BRIEF DESCRIPTION OF THE DRAWINGS

The same numbers are used throughout the drawings to reference like and/or corresponding aspects, features, and components.

FIG. 1 is a block diagram of an example electronic device having a double-sided die.

FIG. 2 is a block diagram of an example front side of a double-sided die.

FIG. 3 is a block diagram of an example edge of the double-sided die that illustrates a cross-sectional view as indicated in FIGS. 2 and 4.

FIG. 4 is a block diagram of an example back side of the double-sided die.

FIG. 5 is a flow diagram that illustrates an example general method for making a double-sided die.

FIG. 6 is a flow diagram that illustrates an example specific method for making a double-sided die.

### DETAILED DESCRIPTION

### Introduction

Integrated circuits (ICs) are typically fabricated on a semiconductor substrate termed a wafer. The wafer is a circular disc of semiconductor material that has been sawed from an elongated semiconductor crystal ingot. The wafer is sufficiently large that it may have dozens, hundreds, or even thousands of a given IC fabricated thereon. Each IC is then singulated by cutting the wafer into dies, each of which has the desired IC disposed on a single side thereof. The die or chip is then packaged in some manner. With conventional IC technology, each die is only utilized on a single side.

In contrast, an example implementation as described herein entails a die that includes a first side having at least one first-side die feature disposed thereon; a second side having at least one second-side die feature disposed thereon; and multiple vias to provide electrical communication between the first side and the second side. The multiple vias connect the first-side die feature to the second-side die feature.

Another example implementation as described herein entails an electronic device that includes a printed circuit board (PCB) and a die having a front side and a back side, with the die including multiple through vias. The front side of the die has multiple bond pads and at least one front-side die feature. The back side of the die has at least one back-side die feature that is in electrical communication with the front-side die feature by way of the multiple through vias. Within the electronic device, the die is attached to the PCB at the multiple bond pads of the front side of the die. By utilizing both sides of the die, the electronic device can be made more cheaply and/or smaller.

In yet another example implementation as described herein, a method includes creating at least one front-side die feature on a front side of a die; creating at least one back-side die feature on a back side of the die; and interconnecting the front-side die feature with the back-side die feature using through vias. The back-side die feature(s) may be, for instance, integrated circuitry, passive components, surface mounted devices (SMDs), and so forth. By thinning the wafer from which the die is singulated, the through vias can be established in each die in a more efficient and/or cost-effective manner.

### Example Electronic Device Having a Double-Sided Die

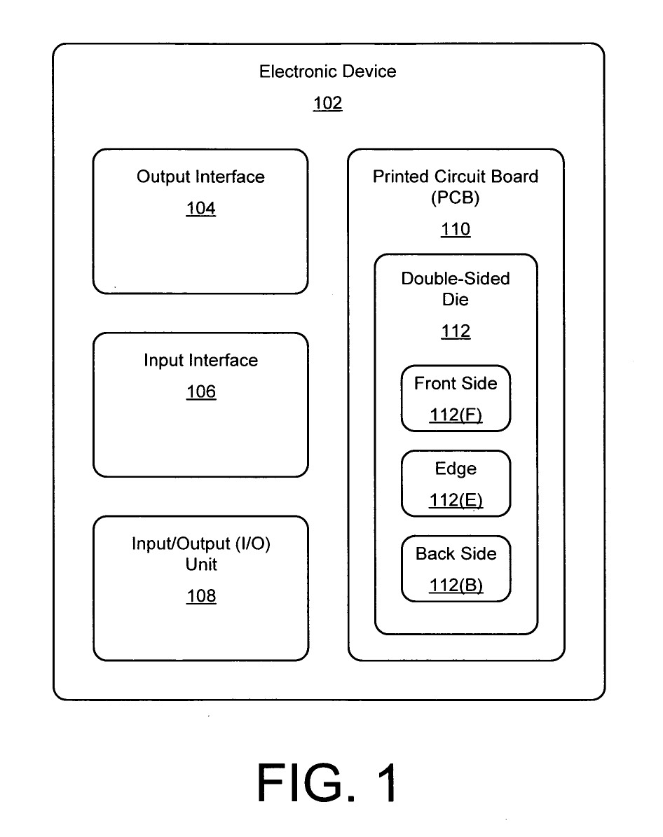

FIG. 1 is a block diagram of an example electronic device 102 having a double-sided die 112. As illustrated, electronic device 102 includes an output interface 104, an input interface 106, an input/output (I/O) unit 108, a printed circuit board (PCB) 110, and a double-sided die 112. Double-sided die 112 includes a front side 112(F), an edge 112(E), and a back side 112(B).

Electronic device 102 may be any device that may include a chip such as a double-sided die 112. Example electronic devices 102 include, by way of example but not limitation, computers (e.g., servers, laptops, hand-helds, etc.), mobile telephones, mobile information appliances (e.g., personal digital assistants (PDAs)), entertainment devices (e.g., televisions, monitors, video recorders/players, digital cameras, video camcorders, digital music players, etc.), game machines (e.g., consoles, portables, etc.), vehicles, adapter/extension modules or cards for such devices, memory cards for such devices, remotes or other input/output interface devices, some combination thereof, and so forth.

Output interface 104 provides output for human consumption. The exact implementation of output interface 104 may depend on the type of electronic device 102 with which it is functioning. Examples of output interfaces 104 include, by way of example but not limitation, an integrated or separate display screen, a speaker, a printer, and so forth.

Input interface 106 enables human input to electronic device 102. The exact implementation of input interface 106 may depend on the type of electronic device 102 with which it is interacting. Examples of input interfaces 106 include, by way of example but not limitation, an integrated or separate keypad or keyboard, a remote, a mouse or other graphical pointing device, a menu manipulator (e.g., a 4-way toggle button, a scroll wheel or pad, etc.), a touch-sensitive screen, and so forth.

I/O unit 108 enables data input and output with other electronic devices and/or electronic systems. The exact implementation of I/O unit 108 may depend on the type of electronic device 102 with which it functions. Examples of I/O unit 108 include, by way of example but not limitation, a modem, a network interface card or other unit, a transmitter and/or receiver (e.g., a wireless transceiver), a local data interface (e.g., Universal Serial Bus (USB), Firewire (IEEE 1394), infrared (IR), etc.), and so forth.

PCB 110 is a board that acts as a foundation for chips and other electronic apparatus. PCBs 110 are typically formed from some type of epoxy and fiberglass, but they may be made of any material. Double-sided die 112 is attached to PCB 110. Attachment schemes may vary, especially depending on the packaging arrangement of the underlying chip. In a described implementation, double-sided die 112 is attached to PCB 110 using a flip-chip packaging arrangement as part of an example wafer-scale packaging implementation.

Double-sided die 112 may ultimately be packaged using any packaging arrangement. Example packaging arrangements include, by way of example but not limitation, the aforementioned flip-chip packaging, as well as using plastic, ceramic, metal, etc. to fully or partially contain the chip. When a double-sided die 112 is to be fully encompassed by some material during packaging, then front side 112(F) and back side 112(B) undergo wafer processing prior to the packaging. With a flip-chip packaging arrangement, on the other hand, the flip-chip packaging may be effectuated after the processing of front side 112(F) but before the processing of back side 112(B).

As noted above, double-sided die 112 includes a front side 112(F), an edge 112(E), and a back side 112(B). For the sake of descriptive clarity, the terms front side and back side are used herein to denote a first side and a second side of double-sided die 112. More specifically, in implementations as described herein, die features are created first on front side 112(F), and die features are created second on back side 112(B). However, either side of a die may be designated a “front” side, and likewise either side of the die may be designated a “back” side.

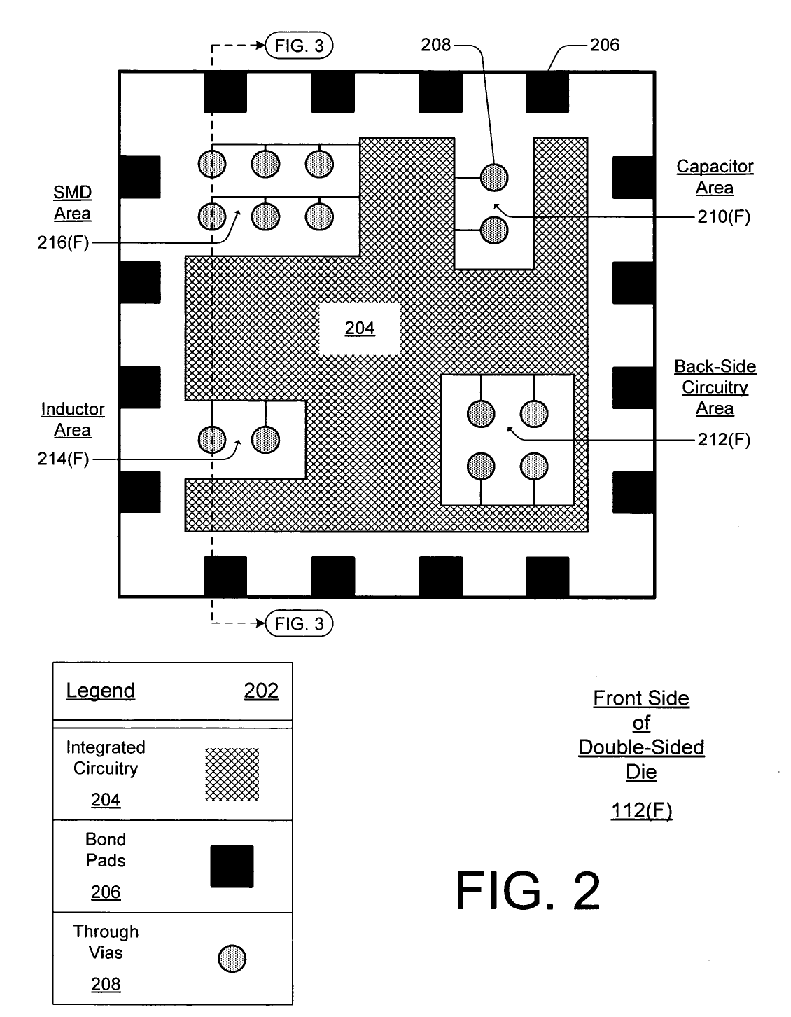

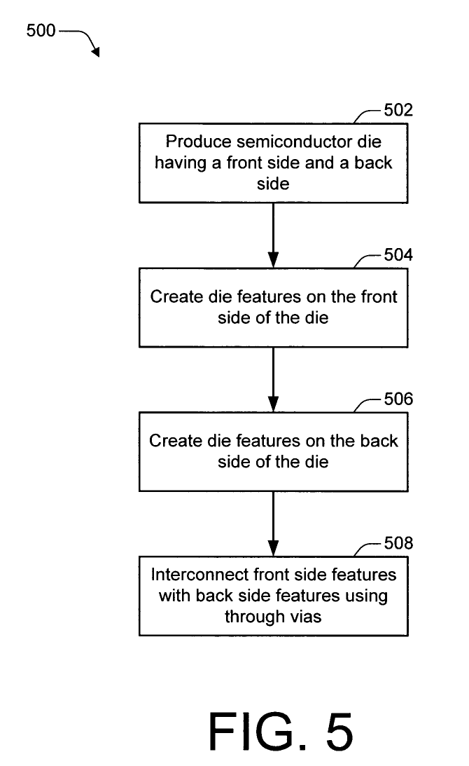

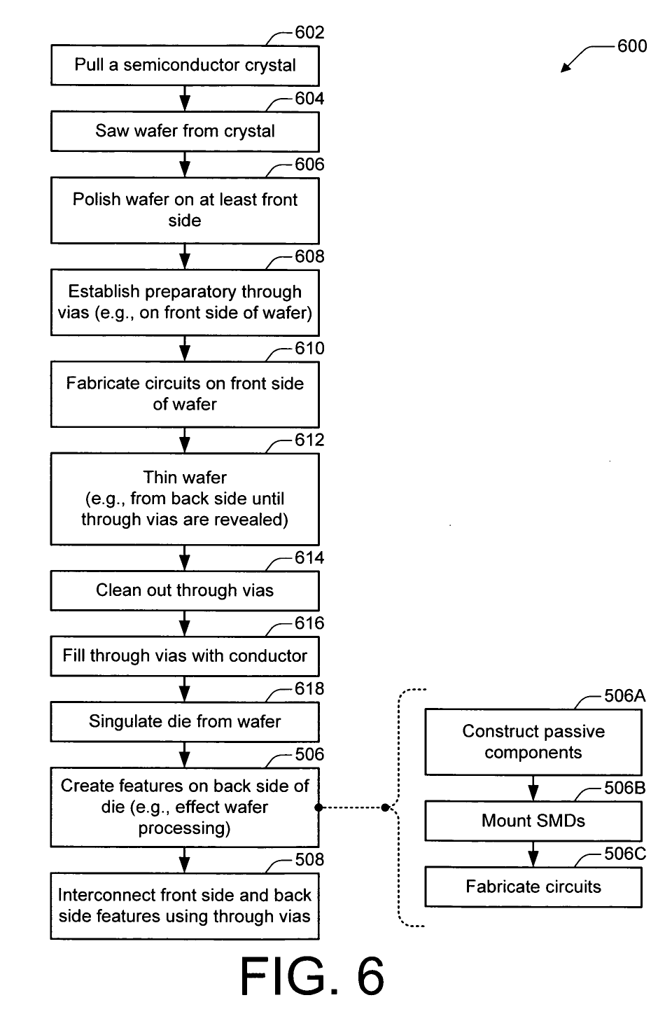

Front side 112(F), edge 112(E), and back side 112(B) are described herein below in the section entitled “Example Double-Sided Die Implementation”. These front, edge, and back parts of double-sided die 112 are described with particular reference to FIGS. 2, 3, and 4, respectively. There is also a section herein below entitled “Example Method of Manufacture for a Double-Sided Die” that references two flow diagrams illustrated in FIGS. 5 and 6.

Electronic device 102 may also have other parts than those that are illustrated in FIG. 1 or described herein. Also, although only one output interface 104, input interface 106, I/O unit 108, and PCB 110 are specifically shown, electronic device 102 may have none or more than two of any of these parts. Moreover, although only a single double-sided die 112 is explicitly illustrated, electronic device 102 may include multiple such double-sided dies 112 that are attached to the same or to different PCBs 110 or that are not attached to a PCB 110.

### Example Double-Sided Die Implementation

FIG. 2 is a block diagram of an example front side 112(F) of a double-sided die 112. Dies are generally singulated from a wafer in a rectangle form, but a die may take any geometric shape. As illustrated, double-sided die 112 is shaped as a square. Double-sided die 112 includes a number of different die elements. It should be noted that double-sided die 112 and the elements thereof are not illustrated to scale in any of FIGS. 2-4.

As indicated by legend 202, these die elements include integrated circuitry 204, bond pads 206, and through vias 208. Integrated circuitry 204 is represented by the areas that are filled with the cross-hatched pattern. Bond pads 206 are represented by solid squares. Through vias 208 are represented by solid-line circles that are filled with a dot pattern.

In a described implementation, bond pads 206 are located along the periphery of front side 112(F). However, they may alternatively be located elsewhere. Also, although sixteen bond pads 206 are illustrated, double-sided die 112 may have fewer or more than sixteen bond pads 206.

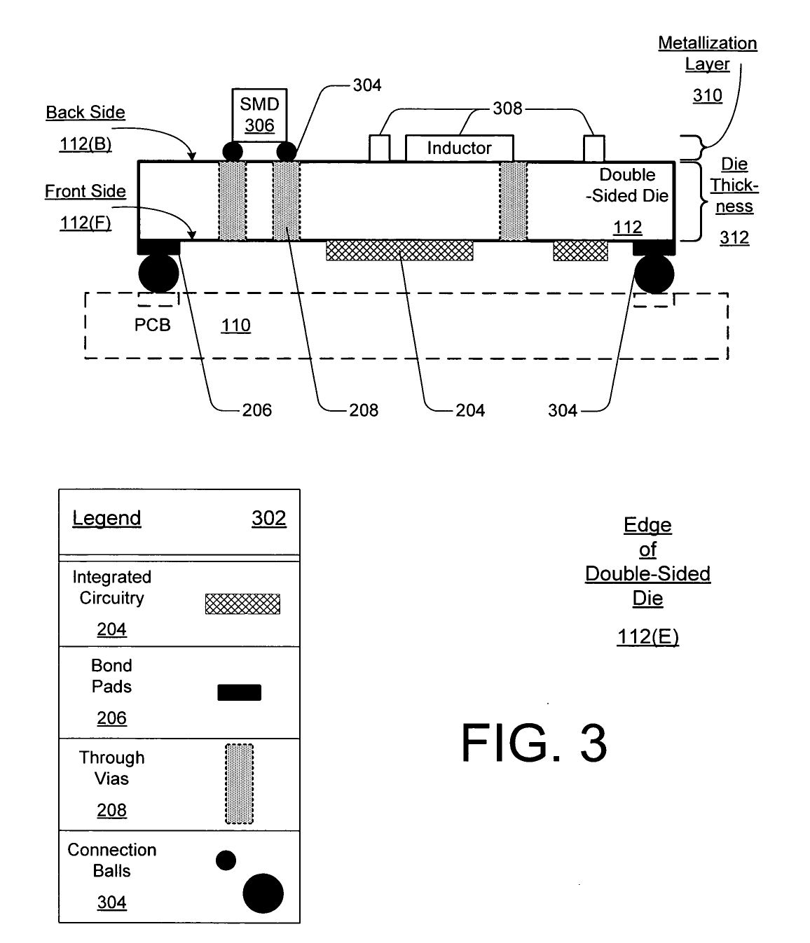

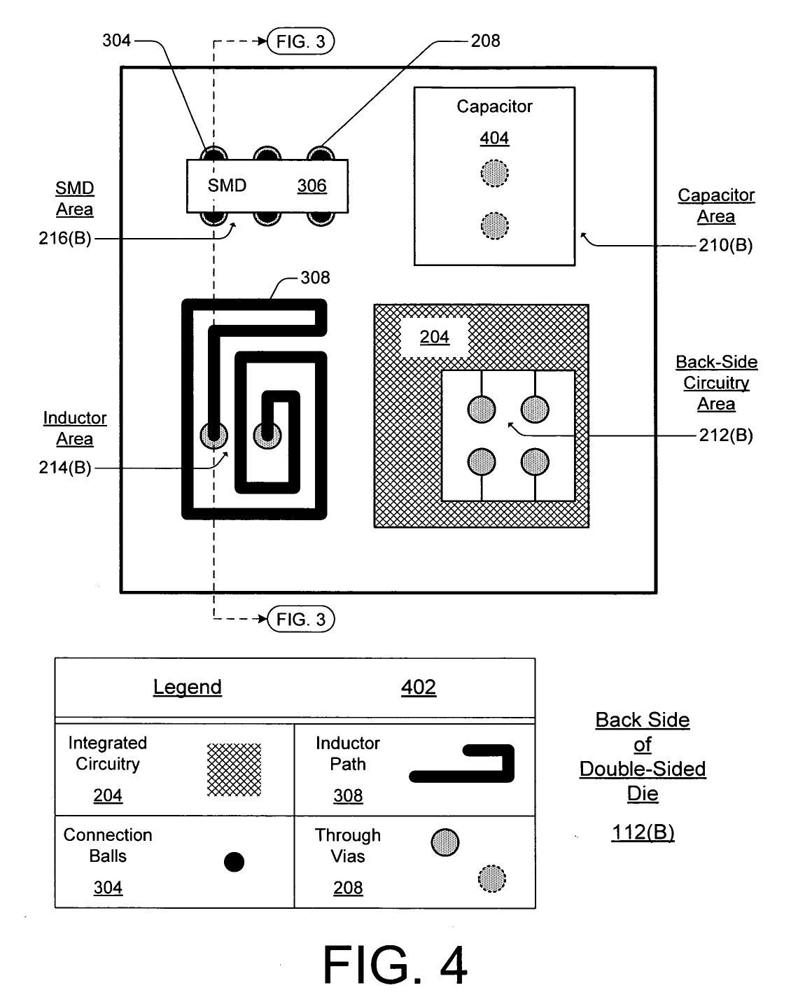

Integrated circuitry 204 occupies much of the interior portion of example front side 112(F). With traditional IC technology, a significant portion of the front (and the only utilized) side of a die would be consumed with other die features, such as passive components. In contrast, with double-sided die 112, other die features are disposed on back side 112(B) (as shown more clearly in FIGS. 3 and 4). Instead of placing the actual other die features on front side 112(F), through vias 208 are used to provide electrical communication between integrated circuitry 204 on front side 112(F) and other die features on back side 112(B).

Regardless, it should be understood that front side 112(F) can still have die features in addition to integrated circuitry 204 disposed thereon. In other words, passive components, SMDs, etc. may be created on front side 112(F). Integrated circuitry 204 is illustrated as being separated from through vias 208 by a buffer zone, except for connection paths (e.g., wires, traces, etc.). However, integrated circuitry 204 may actually be (and likely would be in real-world implementations) closer to through vias 208 and/or more intermingled with through vias 208 than is actually shown in FIGS. 2-4 so as to efficiently utilize the available surface area of double-sided die 112.

The amount of die area consumed by through vias 208 may be significantly less than the amount of die area consumed by the actual other die features. Although this is apparent from a review and consideration of FIGS. 2-4, it would be even more apparent if the double-sided die 112 were drawn to scale. Nevertheless, double-sided die 112 is not drawn to scale to better communicate the concepts of double-sided die utilization.

As illustrated, and by way of example only, double-sided die 112 includes four areas. Each of these four areas is present on front side 112(F) and back side 112(B). Thus, they are designated by “(F)” for front side in FIG. 2 and by “(B)” for back side in FIG. 4. These four areas on front side 112(F) are: capacitor area 210(F), back-side circuitry area 212(F), inductor area 214(F), and SMD area 216(F). Each respective area on front side 112(F) includes one or more through vias 208 that lead to an actual respective die feature on back side 112(B), as is illustrated in FIGS. 3 and 4. Although four areas are shown and described, double-sided die 112 may include fewer or more than four different areas and associated respective die features.

As indicated by the dashed line running “vertically” through double-sided die 112 in FIG. 2 (and FIG. 4), edge 112(E) that is illustrated in FIG. 3 shows a cross-section of double-sided die 112. As is apparent from FIG. 2, edge 112(E) shows two bond pads 206, three through vias 208, and two portions of integrated circuitry 204. As is apparent from FIG. 4, edge 112(E) also shows an SMD (306) and three portions of an inductor (308).

FIG. 3 is a block diagram of an example edge 112(E) of double-sided die 112 that illustrates the cross-sectional view indicated by the dashed line of FIGS. 2 and 4. As illustrated, double-sided die 112 is attached to PCB 110 (of FIG. 1). This view of edge 112(E) includes three newly-illustrated elements: connection balls 304, an SMD 306, and an inductor 308.

As indicated by legend 302, edge 112(E) in FIG. 3 includes integrated circuitry 204, bond pads 206, through vias 208, and connection balls 304. In the cross-sectional view of double-sided die 112, bond pads 206 are represented by solid rectangles, and through vias 208 are represented by dashed-line rectangles that are again filled by the dot pattern. Connection balls 304 are represented by solid circles in two different sizes.

In an example implementation, there is a combination attachment scheme and packaging arrangement termed a flip-chip arrangement for wafer-scale packaging. As also illustrated in FIG. 1, bond pads 206 are disposed on front side 112(F). During the flip-chip packaging, a connection ball (or bump) 304 is placed on each of bond pads 206. The chip or die (e.g., double-sided die 112) is then flipped over and attached to prepared contacts on PCB 110.

As illustrated, the view of edge 112(E) of double-sided die 112 includes, roughly from bottom to top, two larger connection balls 304, two bond pads 206, two portions of integrated circuitry 204, three through vias 208, two smaller connection balls 304, three portions of an inductor 308, and an SMD 306. Integrated circuitry 204 and bond pads 206 are disposed on front side 112(F). Connection balls 304 attach double-sided die 112 to PCB 110 at bond pads 206.

In a described implementation, the substrate of double-sided die 112 includes or forms through vias 208. The length of through vias 208 is determined by die thickness 312. Because the time consumed by etching through vias 208 is roughly directly proportional to die thickness 312 (and time is money in a wafer/chip fabrication plant), the substrate of double-sided die 112 is thinned. This thinning effectively shortens the length of through vias 208.

The wafer from which the die is singulated may be thinned to any desired thickness. However, an example die thickness 312 is approximately 100 micrometers. This 100 micrometer example is thick enough so as to result in a wafer and die of sufficient strength to permit processing thereon. It is also sufficiently thin so as to result in an etching process for through vias 208 that is cost effective. Other examples for die thickness 312 include, by way of example but not limitation, 100-200 micrometers or more and 50-100 micrometers or less.

SMD 306 and inductor 308 are disposed on back side 112(B). By way of example only, SMD 306 is connected to through vias 208 using connection balls 304. Any of connection balls 304 may be of any diameter that is sufficient to enable attachment and connection as well as any desired electrical communication. By way of example only, inductor 308 is constructed in a metallization layer 310. Inductor 308 that is disposed on back side 112(B) may be part of an overall operational circuit for integrated circuitry 204 that is disposed on front side 112(F) without occupying any of the area offered by front side 112(F). This is accomplished using, e.g., two through vias 208 (one of which is illustrated in FIG. 3).

Metallization layer 310 may also include other passive components that are constructed using, e.g., photolithography or other patterning and etching techniques. Passive components include, by way of example but not limitation, a resistor, an inductor, a capacitor, a transformer, a filter, a power combiner, a Balun for radio frequency (RF) applications, and so forth. A transformer constructed on back side 112(B) enables an integrated power amplifier to be created on front side 112(F), which may be particularly useful for wireless device applications for instance.

Such passive components may be constructed using multiple metallization layers 310. Metal capacitors, for example, are often constructed with a first layer of metal, a second layer of metal, and an intervening dielectric that is located between the first and second metal layers. A first through via 208 is connected to the first metal layer, and a second through via 208 is connected to the second metal layer. A dielectric formed on back side 112(B) can be thicker as compared to one formed on front side 112(F); consequently, the Q factor for capacitors can be increased.

FIG. 4 is a block diagram of an example back side 112(B) of double-sided die 112. Back side 112(B) also includes four areas: capacitor area 210(B), back-side circuitry area 212(B), inductor area 214(B), and SMD area 216(B). The actual die features for each of these areas are disposed on back side 112(B) and therefore illustrated in FIG. 4. Example die features include, by way of example but not limitation, integrated circuitry, SMDs, passive components, and so forth.

As indicated by legend 402, back side 112(B) includes integrated circuitry 204, an inductor path 308, connection balls 304, and through vias 208. Integrated circuitry 204 continues to be represented by the cross-hatched pattern. Inductor path 308 is represented by a snaking thick solid line. Connection balls 304 are represented by solid circles. Through vias 208 are represented by solid-line circles and dashed-line circles that are filled with a dot pattern. The dashed-line circles represent through vias 208 that are obscured by another die element (e.g., by capacitor 404).

Capacitor area 210(B) includes a capacitor 404. As described above, capacitor 404 may be built using two different metallization layers that are separated by a dielectric layer. A first through via 208 is electrically connected to one layer or plate of capacitor 404, and a second through via 208 is electrically connected to the other layer or plate of capacitor 404. As is apparent from a comparison of FIGS. 2 and 4, capacitor 404 consumes much more area of back side 112(B) than the two through vias 208 of capacitor area 210(F) consume on front side 112(F).

Back-side circuitry area 212(B) provides additional substrate area for the fabrication of additional integrated circuitry 204. This can enable the total integrated circuitry area on the combined two sides of double-sided die 112 to exceed the maximum area on a single side of a given die. Because each unit of substrate area on a die has an attendant cost, this double-sided die utilization can reduce both the cost of the die and/or the total size of the die. Consequently, double-sided die utilization can also reduce the overall size of an electronic device 102.

Inductor area 214(B) includes an inductor 308 that is snaked (e.g., zigzagged, spiraled, etc.) between two through vias 208. Inductor 308 can thus be incorporated into a circuit that is fabricated as part of the integrated circuitry 204 on front side 112(F) of double-sided die 112 (as illustrated in FIG. 2) (and also as part of the integrated circuitry 204 on back side 112(B)). As is apparent from a comparison of FIGS. 2 and 4, inductor 308 consumes much more area of back side 112(B) than the two through vias 208 of inductor area 214(F) consume on front side 112(F). Moreover, when bond pads 206 (of FIGS. 2 and 3) are absent from back side 112(B), inductor 308 (as well as any die features disposed on back side 112(B)) may extend much closer to the periphery of double-sided die 112 on back side 112(B) as compared to front side 112(F).

SMD area 216(B) includes SMD 306 connected to six through vias 208 using six connection balls 304. More or fewer than six through vias 208 may be utilized to electrically connect SMD 306 to integrated circuitry 204 of front side 112(F) (of FIG. 3). As is apparent from FIG. 4, there is ample surface area on back side 112(B) for SMD 306 to be physically larger without occupying any more area on front side 112(F) than is consumed by the connecting through vias 208. To implement this, the connecting through vias 208 may be spaced farther apart within integrated circuitry 204 of front side 112(F) and/or paths may be created (e.g., in a metallization layer 310) on back side 112(B) that extend from the connecting through vias 208 to the contacts (e.g., bond pads) of a larger SMD 306.

### Example Method of Manufacture for a Double-Sided Die

The two flow diagrams of FIGS. 5 and 6 include multiple blocks that represent actions. Although performance of the actions of these flow diagrams may result in the manufacture of apparatuses that differ from those described herein above, those apparatuses that are illustrated in FIGS. 1-4 are used below to describe example implementations of the methods.

FIG. 5 is a flow diagram 500 that illustrates an example general method for making a double-sided die. Flow diagram 500 includes four (4) blocks 502-508. At block 502, a semiconductor die having a front side and a back side is produced. For example, a double-sided die 112 having a front side 112(F) and a back side 112(B) may be produced.

At block 504, die features on the front side of the die are created. For example, at least one front-side die feature may be created on front side 112(F). At block 506, die features on the back side of the die are created. For example, at least one back-side die feature may be created on back side 112(B). Example front-side and back-side die features include integrated circuitry 204, SMDs 306, passive components (e.g., inductor 308, capacitor 404, etc.), and so forth. At block 508, front side features are interconnected with back side features using through vias. For example, the at least one front-side die feature may be interconnected with the at least one back-side die feature by way of through vias 208 that extend from front side 112(F) to back side 112(B).

FIG. 6 is a flow diagram 600 that illustrates an example specific method for making a double-sided die. Flow diagram 600 includes eleven (11) “primary” blocks 602-618, 506, and 508. Flow diagram 600 also includes three (3) “secondary” blocks 506A, 506B, and 506C.

At block 602, a semiconductor crystal is pulled. For example, a silicon or other semiconductor crystal ingot of a given diameter may be pulled. Example crystal diameters include one inch to twelve inches, but a crystal diameter may be smaller or larger. At block 604, a wafer is sawed from the crystal. The wafer may be of any thickness. However, an example thickness is approximately 1000 micrometers, which is sufficiently strong to enable the wafer to usually survive wafer processing operations.

At block 606, the wafer is polished on at least the front side. Both sides may be polished, but at least one side may be polished to, e.g., optical or mirror-like quality. At block 608, preparatory through vias are established (e.g., on the polished front side of the wafer). For example, preparatory through vias may be established using an etching process. The etching process may be a chemical etch, an ion etch, or some other etching technique. The preparatory through vias may be established to a depth that is approximately the same as the final die thickness 312. In other words, they need not extend all the way through the full original width of the sawed wafer.

At block 610, integrated circuits are fabricated on the front side of the wafer. For example, integrated circuitry 204 may be fabricated on front side 112(F). Other, non-integrated die features may also be created on front side 112(F) at this stage of the wafer processing.

At block 612, the wafer is thinned. For example, after front-side wafer processing is completed, the wafer may be thinned from the back side until the preparatory through vias are revealed to become actual through vias 208. As described above, the wafer may be thinned to any die thickness 312, but an example range about a 100 micrometer thickness is 50-150 micrometers. The wafer may be thinned using a chemically-abrasive slurry, for example.

At block 614, the through vias are cleaned out. At block 616, the through vias are filled with a conductor. For example, a metal may be electroplated into through vias 208. At block 618, a die is singulated from the wafer. For example, a die, which has integrated circuitry 204 fabricated on a front side 112(F), may be cut from the wafer. A wafer may have any number of dies, but an example range is hundreds to thousands of dies per wafer.

After the die has been singulated, back-side processing may be performed next or the die may be packaged next. In a described implementation, the die is first packaged in accordance with a flip-chip packaging arrangement, which is described herein above. The back-side processing is then effected.

At block 506, features are created on the back side of the die. For example, back-side wafer processing may be effected on back side 112(B) of double-sided die 112. Three examples of back-side wafer processing for creating features on the back side of a die are shown by blocks 506A-506C. At block 506A, passive components are constructed. At block 506B, SMDs are mounted. At block 506C, integrated circuits are fabricated. Any one or more of these example die features may be created on back side 112(B).

At block 508, front-side and back-side die features are interconnected using through vias. For example, front-side die features on front side 112(F) may be interconnected with back-side die features on back side 112(B) using through vias 208.

The actions illustrated in flow diagram 600 (and 500) may be performed sequentially. On the other hand, the actions of the blocks may be performed partly, substantially, or completely simultaneously and/or such that they are fully or partially overlapping. As one example, the actions of blocks 506 and 508 may be performed substantially simultaneously when the back-side die features are created so as to be in electrical contact with through vias 208, which automatically results in the interconnection of back-side and front-side die features. As another example, the wafer may be thinned (as in block 612) prior to the establishment of actual through vias. For instance, through vias 208 may be established (e.g., via etching) from front side 112(F) or from back side 112(B) after wafer thinning. When front-side wafer processing has been effected, it is probably safer but not necessary to establish through vias 208 from back side 112(B).

There are many possible alternative manufacturing implementations as well. For example, the back-side wafer processing to create features on back side 112(B) (which is described at block 506) may be performed fully or partially at the wafer stage prior to die singulation (which is described at block 618). Additionally, the side of double-sided die 112 that is to be facing PCB 110 may be created after the other side's features are created. Furthermore, back-side processing may be effected before or after implementation of a flip-chip packaging arrangement onto PCB 110.

The devices, actions, aspects, features, processes, schemes, architectures, arrangements, etc. of FIGS. 1-6 are illustrated in diagrams that are divided into multiple blocks or other elements. However, the order, interconnections, interrelationships, layout, etc. in which FIGS. 1-6 are described and/or shown are not intended to be construed as a limitation, and any number of the blocks or other elements can be modified, combined, rearranged, augmented, omitted, etc. in any manner to implement one or more methods, apparatuses, systems, devices, schemes, dies, electronic devices, arrangements, etc. for double-sided die utilization.

Moreover, although systems, apparatuses, devices, methods, processes, techniques, approaches, arrangements, and other implementations have been described in language specific to structural, logical, methodological, and functional features and/or diagrams, it is to be understood that the invention defined in the appended claims is not necessarily limited to the specific elements or acts described above. Rather, the specific elements and acts described above are disclosed as example forms of implementing the claims.

What is claimed is:

1. An electronic device comprising:
a printed circuit board (PCB); and
a die having a front side and a back side, the die including multiple through vias; the front side of the die including multiple bond pads and at least one front-side die feature, the back side of the die including at least one back-side die feature that is in electrical communication with the at least one front-side die feature by way of the multiple through vias;
wherein the die is attached to the PCB at the multiple bond pads of the front side of the die.

2. The electronic device as recited in claim 1, wherein the die is attached to the PCB at the multiple bond pads of the front side of the die using a flip chip packaging arrangement.

3. The electronic device as recited in claim 1, wherein the electronic device comprises a mobile wireless device.

4. The electronic device as recited in claim 3, wherein the at least one back-side die feature comprises a transformer, and the at least one front-side die feature comprises an integrated power amplifier.

5. The electronic device as recited in claim 1, wherein the at least one front-side die feature comprises integrated circuitry.

6. The electronic device as recited in claim 1, wherein the at least one back-side die feature comprises at least one passive component or at least one surface mounted device (SMD).

7. A die comprising:
a first side including at least one first-side die feature disposed thereon;
a second side including at least one second-side die feature disposed thereon; and
multiple through vias to provide electrical communication between the first side and the second side;
wherein the multiple through vias connect the at least one first-side die feature to the at least one second-side die feature.

8. The die as recited in claim 7, wherein the multiple through vias extend from the first side to the second side, and a length of the multiple through vias is less than 100 micrometers.

9. The die as recited in claim 7, wherein the multiple through vias are filled with a conductor.

10. The die as recited in claim 7, wherein the die comprises a substrate that is a semiconductor, and the at least one first-side die feature comprises integrated circuitry that is fabricated onto the first side.

11. The die as recited in claim 10, wherein the at least one second-side die feature comprises at least one of an inductor or a capacitor.

12. The die as recited in claim 7, wherein the at least one second-side die feature comprises at least one of (i) a passive component that is constructed on the second side, (ii) a surface mounted device (SMD) that is mounted on the second side, or (iii) integrated circuitry that is fabricated onto the second side.

13. The die as recited in claim 12, wherein the passive component comprises at least one of a resistor, an inductor, a capacitor, a transformer, a filter, a power combiner, or a Balun in one or more metallization layers of the second side.

14. The die as recited in claim 7, wherein the multiple through vias comprise a first through via and a second through via; wherein the at least one second-side die feature comprises a capacitor that includes a first metal layer, a second metal layer, and a dielectric layer located between the first and second metal layers; and wherein the first through via is connected to the first metal layer, and the second through via is connected to the second metal layer.

15. A method comprising:
creating at least one front-side die feature on a front side of a die;
creating at least one back-side die feature on a back side of the die; and
interconnecting the at least one front-side die feature with the at least one back-side die feature using through vias.

16. The method as recited in claim 15, wherein the creating at least one front-side die feature comprises:
fabricating one or more integrated circuits on the font side of the die while the die is part of a wafer.

17. The method as recited in claim 15, further comprising:
establish preparatory through vias on the front side of the die while the die is part of a wafer;
thinning the wafer from the back side of the die until the preparatory through vias are revealed to become the through vias to be used in the interconnecting; and
filling the through vias with a conductor.

18. The method as recited in claim 17, further comprising:
singulating the die from the wafer; and
attaching the singulated die to a printed circuit board (PCB) using a flip-chip packaging arrangement.

19. The method as recited in claim 15, further comprising:
after the creating at least one front-side die feature, establishing the through vias in the die from the back side of the die using an etching process.

20. The method as recited in claim 15, wherein the creating at least one back-side die feature comprises at least one of:
constructing one or more passive components on the back side of the die;
mounting one or more surface mounted devices (SMDs) on the back side of the die; or
fabricating one or more integrated circuits on the back side of the die.
